(19) United States
(12) Patent Application Publication
(10) Pub. No.: US 2024/0099144 A1
(43) Pub. Date: Mar. 21, 2024

(54) MANUFACTURING METHOD OF PLANE PIEZOELECTRIC VIBRATION MODULE

(71) Applicant: OMVO TECHNOLOGY INC., Zhubei City (TW)

(72) Inventors: YUE SHIH JENG, Zhubei City (TW); YI HSUN GUU, Hsinchu City (TW)

(21) Appl. No.: 18/368,036

(22) Filed: Sep. 14, 2023

Related U.S. Application Data
(60) Provisional application No. 63/406,731, filed on Sep. 15, 2022.

(51) Int. Cl. H10N 30/045; H10N 30/063; H10N 30/073

(52) U.S. Cl. CPC H10N 30/045; H10N 30/063; H10N 30/073

(57) ABSTRACT

A manufacturing method of a plane piezoelectric vibration module includes: providing a piezoelectric element having a first side and a second side that are opposite; providing a substrate including an insulating bottom layer and an electrode layer, wherein the electrode layer includes a first conduction region, a second conduction region and a patterned insulating groove; disposing an adhesive layer on the electrode layer; disposing the first side of the piezoelectric element on the first conduction region via the adhesive layer, wherein the adhesive layer covers a part of the piezoelectric element; electrically connecting the second side of the piezoelectric element and the second conduction region by using a conduction structure; disposing a protection structure on the electrode layer to cover the piezoelectric element, the adhesive layer and the conduction structure; and finally, applying an electric field to the piezoelectric element to conduct a polarization process on a piezoelectric material layer.

### FIELD OF THE INVENTION

The present invention relates to a technology of a piezoelectric vibration module, and in particular to a manufacturing method of a plane piezoelectric vibration module.

### BACKGROUND OF THE INVENTION

Piezoelectric elements have the characteristics of mutual conversion between mechanical energy and electrical energy and are widely used in piezoelectric vibrators, piezoelectric filters or piezoelectric transformers. In a manufacturing method of a piezoelectric vibration module currently, the piezoelectric element needs to be polarized before a subsequent module manufacturing process. The so-called polarization means that arrangement directions of electric dipole moments are changed after a high-voltage electric field is applied to a piezoelectric material, so that the electric dipole moments originally disposed in random directions are rearranged to have piezoelectric characteristics. However, the process sequence of polarization first and then modularization involves a risk of depolarization of the piezoelectric material due to a modularized high temperature process.

### SUMMARY OF THE INVENTION

The present invention provides a manufacturing method of a plane piezoelectric vibration module, which can avoid the problem of depolarization of the piezoelectric element and allows more types of piezoelectric materials to be selected.

The present invention provides a manufacturing method of a plane piezoelectric vibration module, the manufacturing method including: providing a piezoelectric element, where the piezoelectric element has a first side and a second side that are opposite and includes an unpolarized piezoelectric material layer; providing a substrate, where the substrate includes an insulating bottom layer and an electrode layer, the electrode layer is disposed on the insulating bottom layer and includes a first conduction region, a second conduction region and a patterned insulating groove, and the patterned insulating groove is adapted to insulate the first conduction region and the second conduction region; disposing an adhesive layer on a part of the electrode layer; disposing the first side of the piezoelectric element on the first conduction region via the adhesive layer, wherein the adhesive layer covers a part of the piezoelectric element; electrically connecting the second side of the piezoelectric element and the second conduction region by using a conduction structure; disposing a protection structure on the electrode layer and covering the piezoelectric element, the adhesive layer and the conduction structure; and finally, applying an electric field to the piezoelectric element to conduct a polarization process on a piezoelectric material layer.

In an embodiment of the present invention, the unpolarized piezoelectric material layer includes a first surface and a second surface that are opposite, the piezoelectric element further includes a first metal electrode and a second metal electrode, the first metal electrode is disposed on the first surface to serve as the first side and is disposed on the first conduction region via the adhesive layer, and the second metal electrode is disposed on the second surface to serve as the second side and is electrically connected to the second conduction region by the conduction structure.

In an embodiment of the present invention, the first metal electrode and the second metal electrode are respectively disposed on the first surface and the second surface by a printing process and a sintering process.

In an embodiment of the present invention, the piezoelectric material layer includes a first surface and a second surface that are opposite, the first surface serves as the first side and is disposed on the first conduction region via the adhesive layer, and the second surface serves as the second side and is electrically connected to the second conduction region by the conduction structure.

In an embodiment of the present invention, the piezoelectric material layer includes a first surface and a second surface that are opposite, the piezoelectric element further includes an intermediate layer disposed on the second surface, the first surface serves as the first side and is disposed on the first conduction region via the adhesive layer, and the intermediate layer serves as the second side and is electrically connected to the second conduction region by the conduction structure.

In an embodiment of the present invention, the intermediate layer may be a metal film disposed on the second surface by a sputtering process. In an embodiment, a material of the metal film is titanium.

In an embodiment of the present invention, a material of the adhesive layer is a resin material, and the resin material is cured and further cover a side edge of the piezoelectric element.

In an embodiment of the present invention, when the polarization process is performed, conduction wires are welded on the first conduction region and the second conduction region respectively, and then provide polarization voltage to the conduction wires to apply an electric field to the piezoelectric element and polarize the piezoelectric material layer.

In an embodiment of the present invention, the number of the piezoelectric elements is plural, and the first side of each of the piezoelectric elements is disposed on the first conduction region via the adhesive layer, and the adhesive layer covers a side edge of each of the piezoelectric elements and is filled between the piezoelectric elements.

In the present invention, the step of polarizing the piezoelectric element is arranged after forming the adhesive layer and the protection structure, so that there is no need to worry about the problem of depolarization of the piezoelectric element due to the high-temperature curing process of the adhesive layer and the protection structure. Therefore, in the manufacturing method of the plane piezoelectric vibration module provided by the present invention, the types of the adhesive layer or the piezoelectric material to be selected are more diversified.

### BRIEF DESCRIPTION OF THE DRAWINGS

The present invention will become more readily apparent to those ordinarily skilled in the art after reviewing the following detailed description and accompanying drawings, in which:

FIGS. 1A to 1E are schematic sectional views of various stages of a manufacturing method of a plane piezoelectric vibration module according to a first embodiment of the present invention;

FIGS. 2A to 2C are schematic sectional views of various stages of a manufacturing method of a plane piezoelectric vibration module according to a second embodiment of the present invention;

FIG. 3 is a schematic diagram of another plane piezoelectric vibration module manufactured by the manufacturing method of the plane piezoelectric vibration module according to the second embodiment of the present invention;

FIGS. 4A to 4C are schematic sectional views of various stages of a manufacturing method of a plane piezoelectric vibration module according to a third embodiment of the present invention; and

FIG. 5 is a schematic diagram of another plane piezoelectric vibration module manufactured by the manufacturing method of the plane piezoelectric vibration module according to the third embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

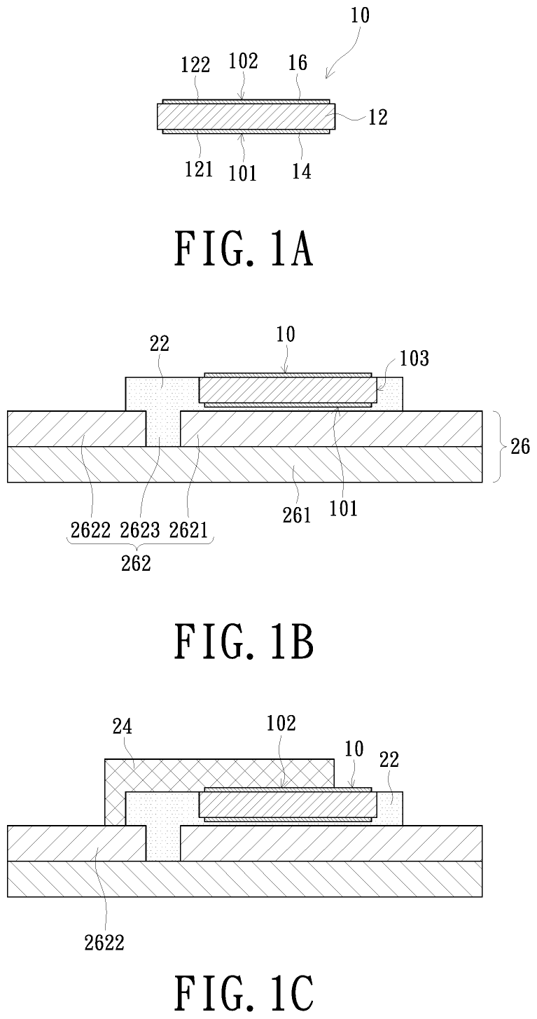

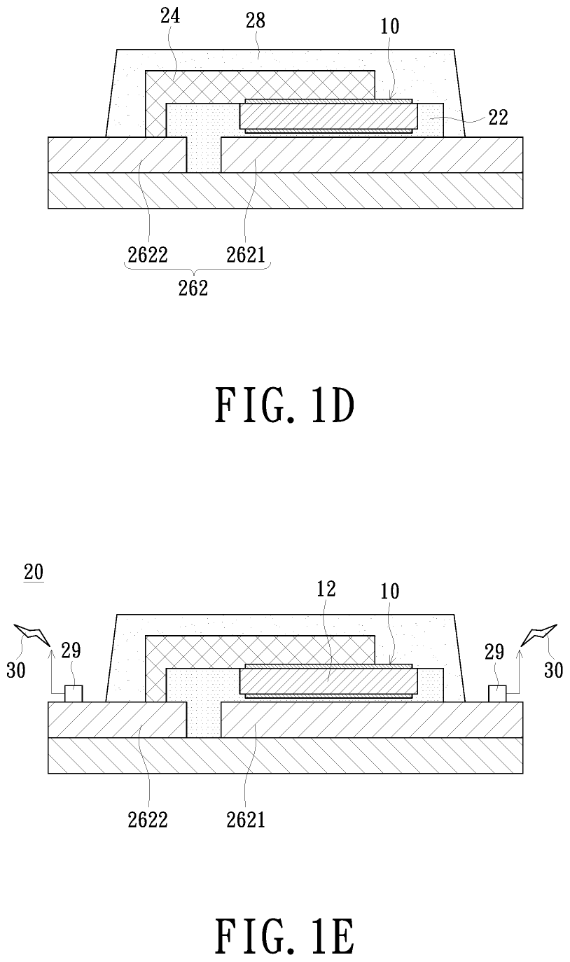

FIGS. 1A to 1E are schematic sectional views of various stages of a manufacturing method of a plane piezoelectric vibration module according to a first embodiment of the present invention. Referring to FIG. 1A, a piezoelectric element 10 is provided, wherein the piezoelectric element 10 has a first side 101 and a second side 102 that are opposite. In an embodiment, the piezoelectric element 10 includes an unpolarized piezoelectric material layer 12, a first metal electrode 14 and a second metal electrode 16, wherein the piezoelectric material layer 12 is sintered at high temperature to a predetermined shape and size and has a first surface 121 and a second surface 122 that are opposite, the first metal electrode 14 is disposed on the first surface 121 to serve as the first side 101 of the piezoelectric element 10, and the second metal electrode 16 is disposed on the second surface 122 to serve as the second side 102 of the piezoelectric element 10. In an embodiment, the first metal electrode 14 and the second metal electrode 16 are respectively disposed on the first surface 121 and the second surface 122 by a printing process and a sintering process.

Referring to FIG. 1B, a substrate 26 is provided, where the substrate 26 includes an insulating bottom layer 261 and an electrode layer 262, the electrode layer 262 is disposed on the insulating bottom layer 261, the electrode layer 262 has a first conduction region 2621, a second conduction region 2622 and a patterned insulating groove 2623, and the patterned insulating groove 2623 is formed between the first conduction region 2621 and the second conduction region 2622.

Next, an adhesive layer 22 is disposed on a part of the electrode layer 262, and before the adhesive layer 22 is cured, the first side 101 of the piezoelectric element 10 is disposed on the first conduction region 2621 via the adhesive layer 22, and the adhesive layer 22 covers a part of the piezoelectric element 10, where the first metal electrode 14 as the first side 101 is electrically connected with the first conduction region 2621. In an embodiment, a material of the adhesive layer 22 is a resin material, and the resin material is cured and further covers a side edge 103 of the piezoelectric element. In an embodiment, as shown in FIG. 1B, the adhesive layer 22 is further filled in the patterned insulating groove 2623 to strengthen the insulation of the first conduction region 2621 and the second conduction region 2622. In an unillustrated embodiment, the material filled in the insulating groove 2623 may be different from that of the adhesive layer 22, that is, an insulating material is filled in the patterned insulating groove 2623, and then the adhesive layer 22 of a different material is disposed on a part of the electrode layer 262.

Next, as shown in FIG. 1C, one end of the conduction structure 24 may be connected to the second side 102 of the piezoelectric element 10 through a low-temperature curing process, and the other end of the conduction structure 24 is electrically connected to the second conduction region 2622, that is, the conduction structure 24 electrically connects the second metal electrode 16 and the second conduction region 2622. In an embodiment, the adhesive layer 22 is filled between the conduction structure 24 and the electrode layer 262.

Next, as shown in FIG. 1D, a protection structure 28 is disposed on the electrode layer 262, and the protection structure 28, for example, spans the first conduction region 2621 and the second conduction region 2622 to cover the piezoelectric element 10, the adhesive layer 22 and the conduction structure 24. In an embodiment, the protection structure 28 may be a molding film, a metal cover or a metal substrate.

Then, an electric field is applied to the piezoelectric element 10 to conduct a polarization process on the piezoelectric material layer 12. Referring to FIG. 1E, specifically, in an embodiment, the conduction wires 29 may be welded on the first conduction region 2621 and the second conduction region 2622 respectively, and then polarization voltage 30 is applied to the conduction wires 29 to apply the electric field to the piezoelectric element 10 and polarize the piezoelectric material layer 12, thus forming a plane piezoelectric vibration module 20.

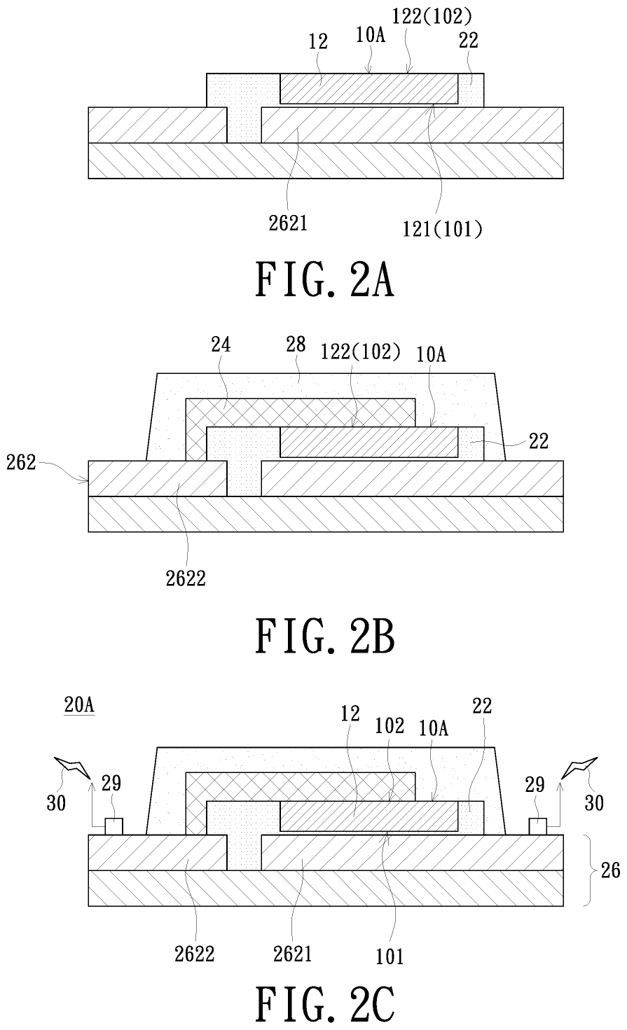

FIGS. 2A to 2C are schematic sectional views of various stages of a manufacturing method of a plane piezoelectric vibration module according to a second embodiment of the present invention. A difference between a manufacturing method of a plane piezoelectric vibration module 20A (shown in subsequent FIG. 2C) of a second embodiment and a manufacturing method of a plane piezoelectric vibration module 20 (shown in FIG. 1E) of a first embodiment is that structures of the piezoelectric elements 10A are different, and in the piezoelectric element 10A, configurations of the first metal electrode 14 (shown in FIG. 1A) and the second metal electrode 16 (shown in FIG. 1A) are omitted. As shown in FIG. 2A, the piezoelectric element 10A includes an unpolarized piezoelectric material layer 12 and has a first side 101 and a second side 102 that are opposite, where the piezoelectric material layer 12 is sintered at high temperature to a preset shape and size and includes a first surface 121 and a second surface 122 that are opposite, the first surface 121 serves as the first side 101 of the piezoelectric element 10A and the second surface 122 serves as the second side 102 of the piezoelectric element 10A. The first side 101 of the piezoelectric element 10A is disposed on the first conduction region 2621 via the adhesive layer 22, and the adhesive layer 22 covers a part of the piezoelectric element 10A.

Next, as shown in FIG. 2B, the second side 102 (i.e., the second surface 122) of the piezoelectric element 10A and the second conduction region 2622 are electrically connected by the conduction structure 24. The structure and connection mode of the conduction structure 24 have been described in the foregoing, and are omitted here. Next, the protection structure 28 is disposed on the electrode layer 262 to cover the piezoelectric element 10A, the adhesive layer 22 and the conduction structure 24.

Then, as shown in FIG. 2C, the electric field is applied to the piezoelectric element 10A, thereby polarizing the piezoelectric material layer 12. Specifically, in an embodiment, the conduction wires 29 may be welded on the first conduction region 2621 and the second conduction region 2622 respectively, and then polarization voltage 30 is applied to the conduction wires 29 to apply the electric field to the piezoelectric element 10A and polarize the piezoelectric material layer 12, thus forming a plane piezoelectric vibration module 20A.

In the manufacturing method of the plane piezoelectric vibration module in the second embodiment, because there is a thin adhesive layer 22 between the piezoelectric material layer 12 and the first conduction region 2621, the piezoelectric material layer 12 and the first conduction region 2621 can be electrically conducted. Therefore, it is unnecessary to print and sinter metal electrodes on the first side 101 and the second side 102, thereby reducing the steps of the manufacturing process, lowering the manufacturing cost and increasing the production yield.

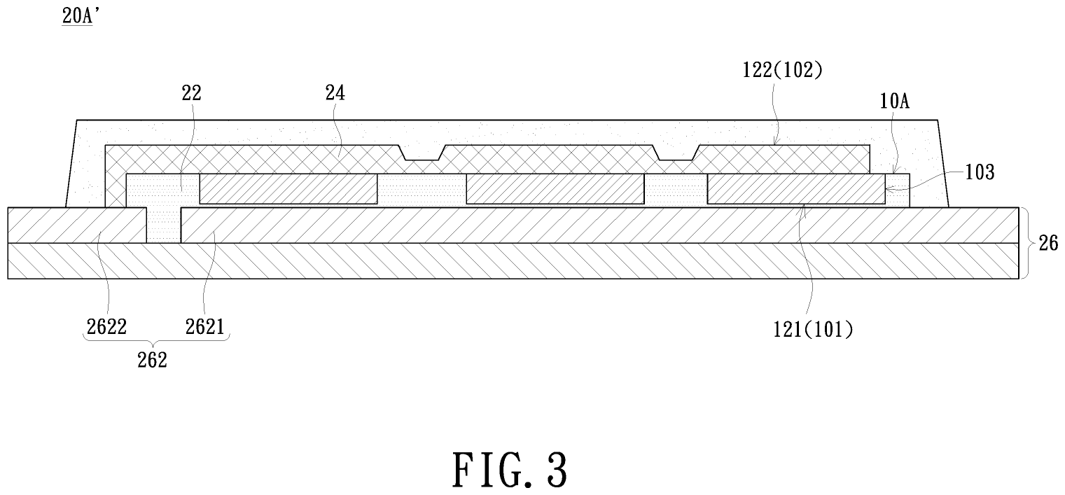

FIG. 3 is a schematic diagram of another plane piezoelectric vibration module manufactured by the manufacturing method of the plane piezoelectric vibration module according to the second embodiment of the present invention. As shown in FIG. 3, the number of piezoelectric elements 10A in the plane piezoelectric vibration module 20A′ may be plural, and the plurality of piezoelectric elements 10A may be arranged on the electrode layer 262 of the substrate 26 in a single layer. For example, as shown in FIG. 3, the plurality of piezoelectric elements 10A are disposed on the first conduction region 2621 in a single layer, where the first sides 101 (i.e., the first surfaces 121) of the plurality of piezoelectric elements 10A are disposed on the first conduction region 2621 via the adhesive layer 22, and the adhesive layer 22 covers side edges 103 of the piezoelectric elements 10A and is filled between the plurality of piezoelectric elements 10A.

Continuing with the above description, referring to FIG. 3, in an embodiment, the conduction structure 24 may be connected to the second sides 102 (i.e., the second surfaces 122) of a plurality of piezoelectric elements 10A by a low-temperature curing process, and the plurality of piezoelectric elements 10A can be electrically connected to the second conduction region 2622. In an embodiment, the adhesive layer 22 is further filled between the conduction structure 24 and the electrode layer 261.

In an unillustrated embodiment, a plurality of piezoelectric elements 10A may also be disposed on the first conduction region 2621, for example, in a laminated element combination, where the first side 101 of the piezoelectric element 10A at the bottommost layer is disposed on the first conduction region 2621 via the adhesive layer 22, and the second side 102 of the piezoelectric element 10A at the topmost layer is fixedly connected with one end of the conduction structure 24 and electrically connected with the second conduction region 2622.

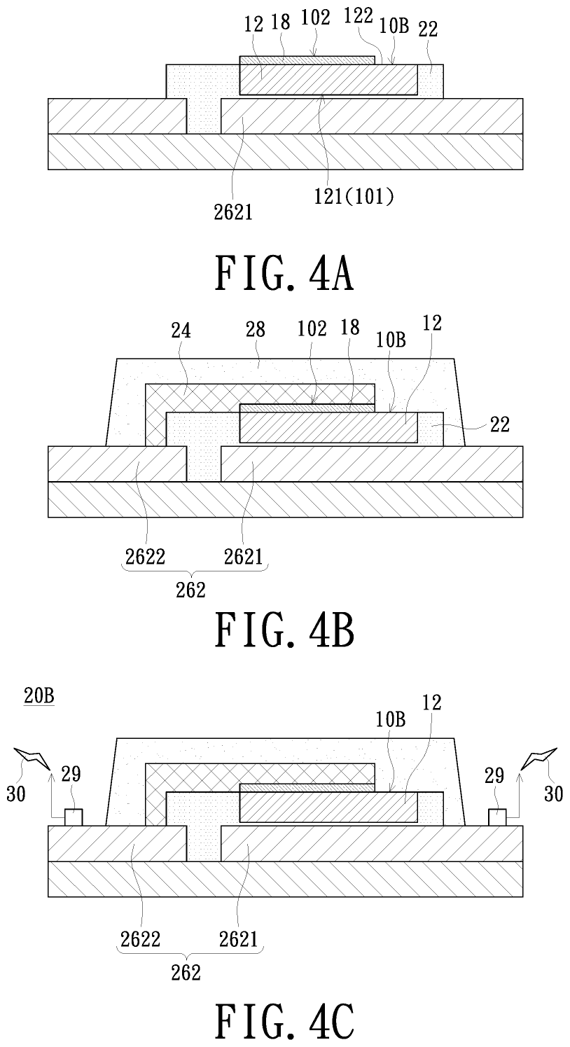

FIGS. 4A to 4C are schematic sectional views of various stages of a manufacturing method of a plane piezoelectric vibration module according to a third embodiment of the present invention. A difference between a manufacturing method of a plane piezoelectric vibration module 20B (shown in FIG. 4C) of a third embodiment and the manufacturing method of the plane piezoelectric vibration module 20A (shown in FIG. 2C) of the second embodiment is that structures of the piezoelectric elements 10B are different. As shown in FIG. 4A, the piezoelectric element 10B includes an unpolarized piezoelectric material layer 12 and an intermediate layer 18, where the piezoelectric material layer 12 is sintered at high temperature to a preset shape and size and includes a first surface 121 and a second surface 122 that are opposite, the first surface 121 serves as the first side 101 of the piezoelectric element 10B and is disposed on the first conduction region 2621 via the adhesive layer 22, and the adhesive layer 22 covers a part of the piezoelectric element 10B. The intermediate layer 18 is disposed on the second surface 122 and serves as the second side 102 of the piezoelectric element 10B. In an embodiment, the intermediate layer 18 may be a metal film disposed on the second surface 122 by a sputtering process, and a material of the metal film is titanium, for example.

Continuing with the above description, as shown in FIG. 4B, the second side 102 (i.e., the intermediate layer 18) of the piezoelectric element 10B and the second conduction region 2622 are electrically connected by the conduction structure 24. The structure and connection mode of the conduction structure 24 have been described in the foregoing, and are omitted here. The intermediate layer 18 makes the conduction structure 24 to be more closely combined with the piezoelectric material layer 12, which contributes to a polarization effect of the piezoelectric material layer 12. Next, the protection structure 28 is disposed on the electrode layer 262 to cover the piezoelectric element 10B, the adhesive layer 22 and the conduction structure 24.

Then, as shown in FIG. 4C, the conduction wires 29 are welded on the first conduction region 2621 and the second conduction region 2622 respectively, and then polarization voltage 30 is applied to the conduction wires 29 to apply the electric field to the piezoelectric element 10B and polarize the piezoelectric material layer 12, thus forming a plane piezoelectric vibration module 20B.

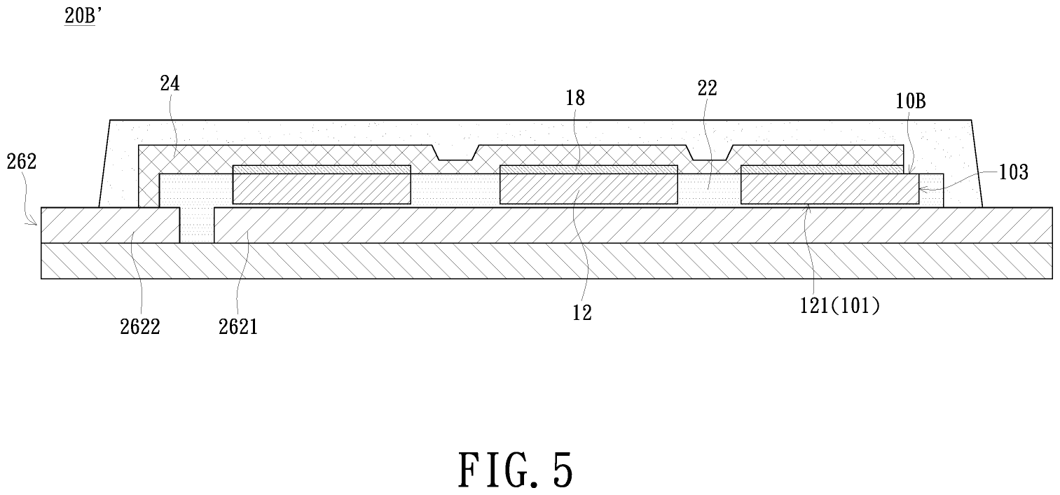

FIG. 5 is a schematic diagram of another plane piezoelectric vibration module manufactured by the manufacturing method of the plane piezoelectric vibration module according to the third embodiment of the present invention. As shown in FIG. 5, the number of piezoelectric elements 10B in the plane piezoelectric vibration module 20B′ may be plural, and the plurality of piezoelectric elements 10B may be arranged on the electrode layer 262 of the substrate in a single layer. For example, as shown in FIG. 5, the plurality of piezoelectric elements 10B are disposed on the first conduction region 2621 in a single layer, where the first sides 101 (i.e., the first surfaces 121) of the plurality of piezoelectric elements 10B are disposed on the first conduction region 2621 via the adhesive layer 22, and the adhesive layer 22 covers, for example, side edges 103 of the piezoelectric elements 10B and is filled between the plurality of piezoelectric elements 10B.

Continuing with the above description, referring to FIG. 5, in an embodiment, the conduction structure 24 may be connected to a plurality of intermediate layers 18 by a low-temperature curing process, and electrically connect the piezoelectric elements 10B and the second conduction region 2622.

In an unillustrated embodiment, a plurality of piezoelectric elements 10B may also be disposed on the first conduction region 2621, for example, in a laminated element combination, where the first side 101 of the piezoelectric element 10B at the bottommost layer is disposed on the first conduction region 2621 via the adhesive layer 22, and the intermediate layer 18 of the piezoelectric element 10B at the topmost layer is fixedly connected with one end of the conduction structure 24 and electrically connected with the second conduction region 2622.

According to the present invention, the polarization step in the manufacturing process of the plane piezoelectric vibration module is arranged after the adhesive layer and the protection structure are formed, so that there is no need to worry about the problem of depolarization of the piezoelectric element during the high-temperature curing process of the adhesive layer and the protection structure, that is, in the manufacturing method of the plane piezoelectric vibration module, there are more types of adhesive layers or piezoelectric materials to be selected, including optional piezoelectric ceramics, lead-free piezoelectric ceramics, piezoelectric polymers, and other materials.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method of a plane piezoelectric vibration module, comprising:
providing at least one piezoelectric element, wherein the at least one piezoelectric element has a first side and a second side that are opposite, and the at least one piezoelectric element comprises an unpolarized piezoelectric material layer;
providing a substrate, wherein the substrate comprises an insulating bottom layer and an electrode layer, the electrode layer is disposed on the insulating bottom layer and comprises a first conduction region, a second conduction region and a patterned insulating groove, and the patterned insulating groove is adapted to insulate the first conduction region and the second conduction region;
disposing an adhesive layer on a part of the electrode layer;
disposing the first side of the at least one piezoelectric element on the first conduction region via the adhesive layer, wherein the adhesive layer covers a part of the at least one piezoelectric element;
electrically connecting the second side of the at least one piezoelectric element and the second conduction region by using a conduction structure;
disposing a protection structure on the electrode layer, wherein the protection structure covers the at least one piezoelectric element, the adhesive layer and the conduction structure; and
applying an electric field to the at least one piezoelectric element to conduct a polarization process on the piezoelectric material layer.

2. The manufacturing method of the plane piezoelectric vibration module of claim 1, wherein the unpolarized piezoelectric material layer comprises a first surface and a second surface that are opposite, the at least one piezoelectric element further comprises a first metal electrode and a second metal electrode, the first metal electrode is disposed on the first surface to serve as the first side and is disposed on the first conduction region via the adhesive layer, and the second metal electrode is disposed on the second surface to serve as the second side and is electrically connected to the second conduction region by the conduction structure.

3. The manufacturing method of the plane piezoelectric vibration module of claim 2, wherein the first metal electrode and the second metal electrode are respectively disposed on the first surface and the second surface by a printing process and a sintering process.

4. The manufacturing method of the plane piezoelectric vibration module of claim 1, wherein the unpolarized piezoelectric material layer comprises a first surface and a second surface that are opposite, the first surface serves as the first side and is disposed on the first conduction region via the adhesive layer, and the second surface serves as the second side and is electrically connected to the second conduction region by the conduction structure.

5. The manufacturing method of the plane piezoelectric vibration module of claim 1, wherein the unpolarized piezoelectric material layer comprises a first surface and a second surface that are opposite, the at least one piezoelectric element further comprises an intermediate layer disposed on the second surface, the first surface serves as the first side and is disposed on the first conduction region via the adhesive layer, and the intermediate layer serves as the second side and is electrically connected to the second conduction region by the conduction structure.

6. The manufacturing method of the plane piezoelectric vibration module of claim 5, wherein the intermediate layer is a metal film disposed on the second surface by a sputtering process.

7. The manufacturing method of the plane piezoelectric vibration module of claim 6, wherein a material of the metal film is titanium.

8. The manufacturing method of the plane piezoelectric vibration module of claim 1, wherein a material of the adhesive layer is a resin material, and the resin material is cured and further covers a side edge of the at least one piezoelectric element.

9. The manufacturing method of the plane piezoelectric vibration module of claim 1, wherein when the polarization process is performed, conduction wires are welded to the first conduction region and the second conduction region respectively, and then polarization voltage is applied to the conduction wires to apply an electric field to the at least one piezoelectric element and polarize the piezoelectric material layer.

10. The manufacturing method of the plane piezoelectric vibration module of claim 1, wherein the number of the at least one piezoelectric element is plural, and the first side of each of the piezoelectric elements is disposed on the first conduction region via the adhesive layer, and the adhesive layer covers a side edge of each of the piezoelectric elements and is filled between the piezoelectric elements.
